(19) United States
(12) Patent Application Publication
(10) Pub. No.: US 2026/0140212 A1
(43) Pub. Date: May 21, 2026

(54) MAGNETIC RESONANCE IMAGING OF WATER-FAT TISSUE

(71) Applicant: The Regents of the University of California, Oakland, CA (US)

(72) Inventor: Yajun Ma, La Jolla, CA (US)

(21) Appl. No.: 19/395,927

(22) Filed: Nov. 20, 2025

Related U.S. Application Data
(60) Provisional application No. 63/723,498, filed on Nov. 21, 2024.

(51) Int. Cl. G01R 33/48; G01R 33/56

(52) U.S. Cl. CPC G01R 33/4828; G01R 33/4824; G01R 33/5607

(57) ABSTRACT

Disclosed are devices, systems, and methods for magnetic resonance imaging of water-fat tissue, which provide a new MRI pulse sequence designed for improved water-fat imaging. In some aspects, a magnetic resonance imaging (MRI) method for characterizing tissue includes acquiring magnetic resonance (MR) data from a tissue using an MRI system in accordance with a spectrally-selective and interleaved water imaging and fat imaging (siWIFI) procedure that uses a narrow bandwidth radio frequency (RF) pulse sequence that alternately excites water and fat separately in a tissue; and processing the acquired MR data to produce images from the acquired MR data that depicts the water content and the fat content in the tissue.

### CROSS-REFERENCE TO RELATED APPLICATIONS

This patent document claims priority to and benefits of U.S. Provisional Patent Application No. 63/723,498, titled “MAGNETIC RESONANCE IMAGING OF WATER-FAT TISSUE” and filed on Nov. 21, 2024. The entire contents of the aforementioned patent application are incorporated by reference as part of the disclosure of this patent document.

### STATEMENT REGARDING FEDERALLY SPONSORED RESEARCH OR DEVELOPMENT

This invention was made with government support under AR079484 awarded by the National Institutes of Health. The government has certain rights in the invention.

### TECHNICAL FIELD

This patent document relates to magnetic resonance imaging (MRI) technology.

### BACKGROUND

Fat tissue content is an important biomarker for different health conditions. In many metabolic disorders, fat tissue triggers chronic inflammation, which can progress to fibrosis.

### SUMMARY

Disclosed are devices, systems and methods for magnetic resonance (MR) imaging of water-fat tissue. In some embodiments, an MR imaging technique, also referred to herein as spectrally-selective and interleaved water imaging and fat imaging (siWIFI), uses a narrow bandwidth RF pulse for selective excitation of water and fat separately.

The disclosed embodiments include systems and methods for characterizing tissue by generating co-registered water and fat images. In an aspect, an example method for characterizing tissue includes alternatively applying radio frequency (RF) pulses of a first type and a second type to generate first magnetic resonance (MR) data and second MR data, respectively, wherein the RF pulses of the first type selectively excite water, and wherein the RF pulses of the second type selectively excite fat. The example method further includes processing the first MR data to produce a first MR image, wherein the first MR image depicts water intensity data; and processing the second MR data to produce a second MR image, wherein the second MR image depicts fat intensity data.

In another aspect, an example non-transitory, computer-readable storage medium includes instructions recorded thereon, wherein the instructions when executed by at least one data processor of a magnetic resonance imaging (MRI) device, cause the MRI device to alternatively apply radio frequency (RF) pulses of a first type and a second type to generate first magnetic resonance (MR) data and second MR data, respectively. The instructions further cause the at least one data processor to process the first MR data to produce a first MR image, and process the second MR data to produce a second MR image.

In various implementations of the present technology, the disclosed methods, devices, and systems can provide precise fat quantification throughout the body, in a more accurate way than current methods. The disclosed techniques are envisioned to improve the diagnosis of different health conditions, as well as expand the use of MRI for diagnostic and monitoring purposes.

The subject matter described in this patent document can be implemented in specific ways that provide one or more of the following features.

### BRIEF DESCRIPTION OF THE DRAWINGS

FIGS. 1A-1C show diagrams and an image depicting an example embodiment of a spectrally-selective and interleaved water imaging and fat imaging (siWIFI) pulse sequence in accordance with the present technology.

FIGS. 2A-2C show example phantom siWIFI imaging results from example implementations of an example embodiment of the disclosed siWIFI technique.

FIG. 3 shows example imaging results of a hip acquired from a subject by an example embodiment of the siWIFI technique and the conventional IDEAL imaging technique.

FIG. 4 shows example imaging results of a knee acquired from a subject by an example embodiment of the siWIFI technique and the conventional IDEAL imaging technique.

FIG. 5 shows example imaging results of a liver acquired from a subject by an example embodiment of the siWIFI technique and the conventional IDEAL imaging technique.

FIG. 6 shows example data plots comparing fat fractions between an example embodiment of the siWIFI technique and the conventional IDEAL imaging technique.

FIG. 7 shows example images and a data plot depicting simultaneous magnetization transfer ratio (MTR) and fat fraction mapping via an example embodiment of a MT-siWIFI technique, in accordance with the present technology.

FIG. 8 shows example images and a data plot depicting B₀ inhomogeneity tolerance of siWIFI fat fraction measurements from example implementations of an example embodiment of the disclosed siWIFI technique.

FIG. 9 shows example images depicting in vivo siWIFI fat fraction maps with and without fat peak correction, and comparisons with IDEAL fat fraction maps, based on example implementations of an example embodiment of the siWIFI technique and the conventional IDEAL imaging technique.

FIG. 10 shows a flow diagram illustrating an example method for characterizing tissue by selectively imaging water and fat.

FIG. 11 shows a diagram of an example embodiment of a system for implementing example embodiments of the siWIFI technique in accordance with the present technology.

### DETAILED DESCRIPTION

Disclosed are devices, systems and methods for magnetic resonance imaging of water-fat tissue, which provide a new MRI pulse sequence designed for improved water-fat imaging.

Currently, conventional magnetic-resonance imaging (MRI) requires post-processing to distinguish between fat tissue and water in the body. This type of imaging is susceptible to errors and motion artifacts as it requires the patient to hold their breath during a scan.

As an example of such conventional MRI techniques, currently, Dixon-based methods, including iterative decomposition of water and fat with echo asymmetry and least-squares estimation (IDEAL), are extensively employed for water-fat separation and quantification. Such existing methods leverage the chemical shift difference between the water and fat protons by acquiring multiple echo images at various TEs followed by either simple subtraction and addition of images or fitting to a signal model that accommodates field inhomogeneity and R2*. Having demonstrated successful separation of water and fat signals in musculoskeletal and abdominal imaging, these methods are widely integrated into clinical practice. However, they are susceptible to water-fat swap errors and motion-induced artifacts, necessitating breath-holding during abdominal imaging.

Fat content serves as an important biomarker for various metabolic and inflammatory diseases. In many metabolic disorders, fat infiltration triggers chronic inflammation, which can progress to fibrosis, as seen in the progression from fatty liver to liver cirrhosis. The disclosed technology provides a novel MRI sequence that enables precise fat quantification throughout the body, outperforming existing MR imaging methods. The disclosed MRI technique is well-suited for clinical translation due to its simplicity and robustness against motion artifacts. Moreover, the disclosed MRI technique can be combined with other MR imaging biomarkers, offering significant potential for accurate monitoring of metabolic and inflammatory conditions, where fat infiltration and fibrosis frequently occur.

In some embodiments of the disclosed MRI techniques, an MRI pulse sequence is configured to selectively excite water and fat protons in an interleaved manner, reducing error and removing the need for post-processing. In some embodiments of the disclosed MRI technique, for example, radial sampling techniques are used to reduce motion blur. Example implementations of the disclosed MRI techniques show that the results provide a better, more accurate imaging of the tissue for MRI. The disclosed MR imaging technique may also be referred to as spectrally-selective and interleaved water imaging and fat imaging (siWIFI).

For example, the disclosed methods can provide an MR imaging sequence that independently acquires water and fat images while being inherently insensitive to motion. Example implementations of the disclosed methods demonstrate that siWIFI can be further combined with other quantitative MRI techniques, e.g., an MT preparation module can be incorporated into the siWIFI sequence.

The siWIFI MRI technique provides a pulse sequence designed for targeted water-fat imaging and quantification. The siWIFI sequence selectively excites water and fat protons in an interleaved manner, ensuring inherent co-registration of water and fat images. Additionally, a radial sampling strategy is employed to mitigate motion-induced artifacts.

The disclosed siWIFI method can leverage the chemical shift of fat for spectral selection using a narrow bandwidth RF pulse. Typically, for example, fat saturation is performed using a maximum-phase pulse to maximize the signal decay during RF excitation, followed by a spoiler gradient. In contrast with conventional spectrally-selective fat saturation techniques, the disclosed siWIFI sequence employs a minimum-phase design to achieve minimized TE for the effective excitation of water and fat signals, rather than saturating them. Furthermore, the siWIFI technique not only generates water-selective images but also quantifies fat fractions, whereas fat saturation is typically utilized solely for water imaging.

In some embodiments of the disclosed siWIFI technology, a siWIFI MRI method for characterizing tissue includes alternatively applying radio frequency (RF) pulses of a first type and a second type to generate first magnetic resonance (MR) data and second MR data, respectively, where the RF pulses of the first type selectively excite water, and where the RF pulses of the second type selectively excite fat; processing the first MR data to produce a first MR image, where the first MR image depicts water intensity data; and processing the second MR data to produce a second MR image, where the second MR image depicts fat intensity data.

In some implementations of the exemplary siWIFI MRI method, for example, the RF pulses of the first type and the RF pulses of the second type have a bandwidth of less than 400 Hz or a duration of greater than 6 ms. In some implementations of the exemplary siWIFI MRI method, for example, the RF pulses of the first type and the RF pulses of the second type have a peak-to-end duration of less than 3 ms. In some implementations of the exemplary siWIFI MRI method, for example a repetition time (TR) is between 8 ms and 15 ms; and/or in some implementations, an echo time (TE) is between 2 ms and 2.5 ms. In some implementations of the exemplary siWIFI MRI method, for example, each RF pulse of the first type corresponds to a radial spoke of k-space data in the first MR data, and wherein each RF pulse of the second type corresponds to a radial spoke of k-space data in the second MR data.

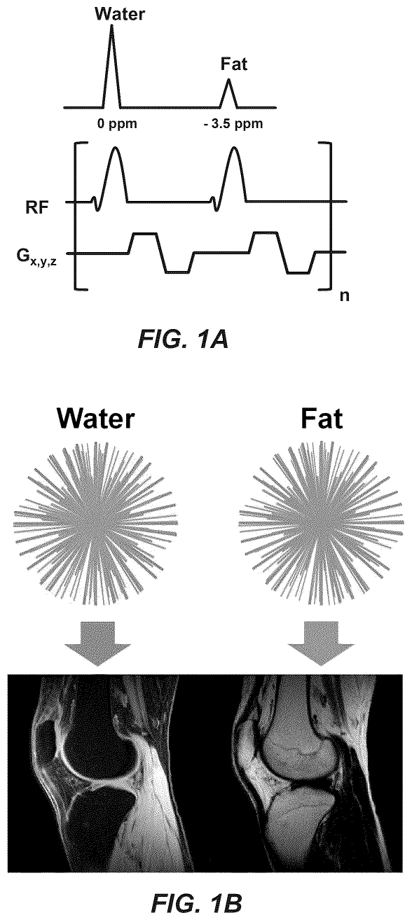

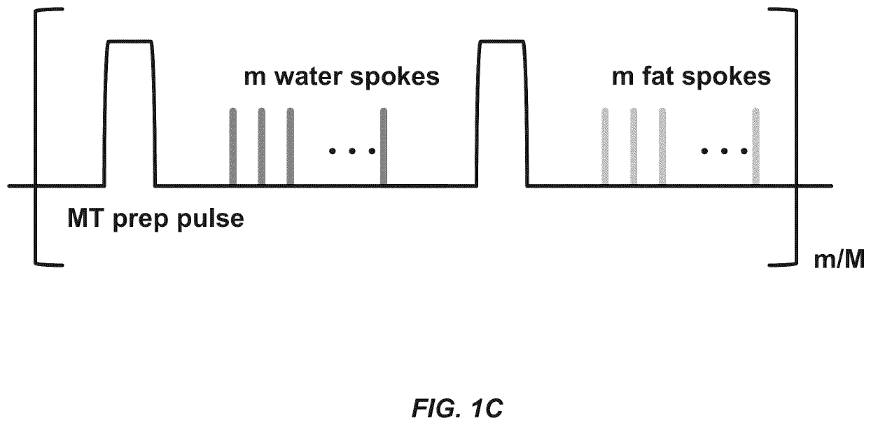

FIGS. 1A, 1B, and 1C show diagrams and an image depicting an example embodiment of an siWIFI pulse sequence in accordance with the present technology. For example, the siWIFI technique can utilize a narrow bandwidth soft pulse design (e.g., with a duration of 6.6 ms and a spectral bandwidth of 333 Hz), and the siWIFI sequence can enable spectrally selective imaging of water and fat. In some example embodiments, the siWIFI technique can achieve a peak-to-end duration of 2.3 ms with a minimum-phase design, and a 3D center-out radial readout scheme can be employed for data acquisition. For some example embodiments, consequently, the minimum TE achievable with this center-out scheme is 2.3 ms, which is close to the in-phase condition for water and fat at 3T. Interleaved acquisition is achieved by alternately tuning the carrier frequency of the narrow bandwidth excitation pulse between water (e.g., 0 ppm) and fat frequency (e.g., −3.5 ppm or −445 Hz at 3T) for each k-space line acquisition, as illustrated in FIG. 1A. Subsequently, k-space lines acquired in this interleaved fashion are reorganized for reconstruction, yielding distinct water and fat images as depicted in FIG. 1B. As a result, water and fat images can be inherently co-registered.

For example, due to the relatively narrow bandwidth of the siWIFI RF pulse (e.g., 333 Hz), only five fat peaks (e.g., 0.9, 1.2, 1.6, 2.0, and 2.3 ppm) are excited for fat-selective imaging, accounting for ˜87.8% of the total area of the full-fat spectrum. Thus, the acquired siWIFI fat images are normalized using this ratio. siWIFI water images also require adjustment due to the presence of four additional fat peaks (e.g., 4.1, 4.3, 5.2, and 5.3 ppm) near the water peak. These peaks represent ˜10.66% of the total fat peak area. Consequently, for example, the siWIFI water images can be adjusted by subtracting 12.14% of the siWIFI fat signal intensity. After these adjustments, fat fraction maps can be calculated, e.g., by normalizing the siWIFI fat image by the sum of siWIFI water and fat images.

Example implementations were performed using example embodiments of the disclosed siWIFI technique. In some example implementations, for example, lipid phantom and in vivo hip, knee, and liver studies are conducted to assess the feasibility of siWIFI for fat fraction quantification and to compare its performance with vendor-provided IDEAL. The fat fraction quantification of si WIFI was validated using microlipid phantom scans, which showed an excellent correlation between the measured fat fraction and the actual fat concentrations in the series of phantoms. In vivo scans of healthy volunteers at various anatomical regions showed robust separation of water and fat images, with fat fraction measurements aligning with those from IDEAL scans. Notably, the motion artifacts from blood flow and respiration observed in IDEAL scans were much reduced in siWIFI images.

Example Embodiments and Example Implementations of the Disclosed siWIFI Techniques

Example embodiments and example implementations demonstrating the disclosed siWIFI techniques are described in detail below.

Fat content is a valuable biomarker of many metabolic and inflammatory diseases. Metabolic diseases often involve fat infiltration, which in turn causes chronic inflammation and leads to fibrosis, as exemplified by the sequence of fatty liver-to-liver cirrhosis development. On the other hand, fat represents a significant source of artifacts in numerous morphological and quantitative MRIs. Fat signal exhibits relatively high intensity in both T₂- and T₁-weighted images owing to its long T₂ and short T₁ characteristics. These strong fat signals compromise tissue contrast, thereby impeding precise morphological analysis. Furthermore, fat signal interferences also impact quantitative MR measurements crucial for pathology characterization and subsequent disease diagnosis. Given the significance of these issues in MR imaging, the effective separation of water and fat has garnered considerable interest. This separation is not only essential for achieving distinct contrast and accurate fat measurement but also for accurately measuring other quantitative MR parameters, such as Tip and susceptibility, that reflect underlying pathologies.

Currently, Dixon-based methods, including iterative decomposition of water and fat with echo asymmetry and least-squares estimation (IDEAL), are extensively employed for water-fat separation and quantification. These methods leverage the chemical shift difference between the water and fat protons by acquiring multiple echo images at various TEs followed by either simple subtraction and addition of images or fitting to a signal model that accommodates field inhomogeneity and R₂*. Demonstrating successful separation of water and fat signals in musculoskeletal and abdominal imaging, these methods are widely integrated into clinical practice. However, they are susceptible to water-fat swap errors and motion-induced artifacts, necessitating breath-holding during abdominal imaging.

The example implementations described herein demonstrate novel and simple pulse sequences of the disclosed siWIFI technique designed for targeted water-fat imaging and quantification. The exemplary siWIFI sequence selectively excites water and fat protons in an interleaved manner, ensuring inherent co-registration of water and fat images. Additionally, a radial sampling strategy is employed to mitigate motion-induced artifacts. Both phantom and in vivo studies are conducted to assess the feasibility of siWIFI for fat fraction quantification and to compare its performance with vendor-provided IDEAL. Furthermore, a magnetization transfer (MT) preparation module is integrated into the siWIFI framework (MT-siWIFI), enabling simultaneous measurement of fat fraction and MT ratio (MTR).

### si WIFI Sequence

Example embodiments of the siWIFI Sequence are described. As shown in FIG. 1A, the overall design of the disclosed siWIFI pulse sequence utilizes a narrow bandwidth soft pulse design (e.g., with a duration of 6.6 ms and a spectral bandwidth of 333 Hz), which the siWIFI sequence can use to enable spectrally selective imaging of water and fat. As shown in FIG. 1A, a peak-to-end duration of 2.3 ms can be achieved with a minimum-phase design, for example, and a 3D center-out radial readout scheme is employed for data acquisition. Consequently, the minimum TE achievable with this center-out scheme is 2.3 ms, which is close to the in-phase condition for water and fat at 3T. Interleaved acquisition is achieved by alternately tuning the carrier frequency of the narrow bandwidth excitation pulse between water (e.g., 0 ppm) and fat frequency (e.g., −3.5 ppm or −445 Hz at 3T) for each k-space line acquisition (e.g., each k-space spoke acquired), as shown in FIG. 1A. This interleaved water and fat excitation and readout are repeated (n) times until the 3D k-spaces are fully sampled. Data acquisition utilizes a 3D center-out radial sampling method. Following the acquisition, interleaved spokes are regrouped and reconstructed to generate separate water and fat images. Subsequently, k-space lines acquired in this interleaved fashion are reorganized for reconstruction, yielding distinct water and fat images, as depicted in FIG. 1B. As a result, water and fat images are inherently co-registered. The siWIFI sequence was implemented on a clinical 3T scanner (e.g., MR750, GE Healthcare Technologies Inc., Milwaukee, WI) for phantom and in vivo scans.

siWIFI Fat Peak Correction

Due to the relatively narrow bandwidth of the siWIFI RF pulse (e.g., 333 Hz), only five fat peaks (e.g., 0.9, 1.2, 1.6, 2.0, and 2.3 ppm) are excited for fat-selective imaging, accounting for ˜87.8% of the total area of the full-fat spectrum. Thus, the acquired siWIFI fat images are normalized using this ratio. siWIFI water images also require adjustment due to the presence of four additional fat peaks (e.g. 4.1, 4.3, 5.2, and 5.3 ppm) near the water peak. These peaks represent ˜10.66% of the total fat peak area. Consequently, for example, the siWIFI water images should be adjusted by subtracting 12.14% of the siWIFI fat signal intensity. After these adjustments, fat fraction maps are calculated by normalizing the siWIFI fat image by the sum of siWIFI water and fat images.

### Lipid Phantom Study

Lipid phantoms were created with varying concentrations (e.g., 0, 6, 10, 20, 30, 40, 50% by volume) of dietary fat emulsion (Microlipid, Nestle Health Science, Hoboken, NJ) mixed in water. These phantoms were scanned with the siWIFI sequence, employing an 8-channel knee coil and the following scan parameters: TR/TE=11.5/2.3 ms, flip angle (FA)=6°, field-of-view (FOV)=10 cm×10 cm, matrix=180×180, slice thickness (ST)=3.6 mm, number of slices=36, number of excitations (NEX)=1.7, with a scan time of 5 minutes and 58 seconds.

### In Vivo Hip, Knee, and Liver Imaging

All in vivo investigations were conducted with the approval of the Institutional Review Board at the University of California, San Diego, and informed consent was obtained from all participants. Healthy volunteers were recruited for hip (e.g., 29.0±3.9 years old, 3 male and 1 female), knee (e.g., 29.6±4.0 years old, 3 male and 2 female), and liver (e.g., 35.3±5.9 years old, 4 male) imaging using both siWIFI and IDEAL techniques. In liver imaging, IDEAL scans were conducted twice, either with free breathing (IDEAL FB) or breath-hold (IDEAL BH), whereas siWIFI scans were performed during free breathing. The 8-channel knee coil was used for knee imaging, while an 8-channel cardiac coil was used for liver and hip imaging. Detailed sequence parameters for the in vivo study are outlined in Table 1. For each anatomical region, one subject underwent three scans to assess the repeatability of siWIFI scans, with the system being reset before each scan.

TABLE 1
In vivo scan parameters of siWIFI and IDEAL.
n represents the number of subjects.

| | Hip (n = 4) | | Knee (n = 5) | | Liver (n = 4) | |
|---|---|---|---|---|---|---|
| | siWIFI | IDEAL | siWIFI | IDEAL | siWIFI | IDEAL |
| TR/TE (ms) | 11.8/2.5 | 8.7/8 | 12/2.3 | 10.7/8 | 9.7/2.4 | 5.8/6 |
| | | echoes, | | echoes, | | echoes, |
| | | 1.6-6.7 | | 2.1-8.2 | | 0.9-4.4 |
| FA (deg) | 6 | 4 | 5 | 4 | 6 | 3 |
| FOV (cm) | 42 × 42 | | 16 × 16 | | 44 × 44 | |
| Matrix | 256 × 256 | | 256 × 256 | | 160 × 160 | 256 × 256 |
| Slice Thickness | 6 | | 3 | | 10 | |
| (mm) | | | | | | |
| Slice # | 40 | | 34 | | 24 | |
| NEX | 1.3 | 1 | 1.1 | 1 | 2 | 0.5 |
| rBW | 125 kHz | | 125 kHz | 200 kHz | 125 kHz | 222 kHz |
| Scan Time | 5:54 | 6:00 | 5:42 | 5:41 | 5:32 | 0:21 |

### Simultaneous Fat Fraction and Magnetization Transfer Ratio Measurement

To demonstrate that siWIFI can be combined with other quantitative MRI techniques, an MT preparation module was incorporated into the siWIFI sequence (i.e., MT-siWIFI). FIG. 1C depicts an MT-prepared siWIFI (MT-siWIFI) diagram. The designed MT-siWIFI sequence is similar to our previous multi-spoke ultrashort echo time (UTE) MT sequence, which acquires multiple radial spokes after each MT prep pulse (defined as one segment). In this approach, MT-siWIFI acquires data in an interleaved fashion: one MT pulse is followed by a water imaging segment, and the adjacent MT prep pulse is followed by a fat imaging segment. The alternating water and fat segments lead to the interleaved acquisition of MT-prepared water and fat images once the full k-spaces are covered (e.g., fully sampled). The number of water and fat spokes in each segment (m) can be adjusted; in this study, it was set to 9. M is defined as the total number of segments needed to cover the entire k-space.

One of the volunteers (e.g., 32-year-old female) recruited for knee siWIFI imaging was also scanned with the MT-siWIFI sequence using the following parameters: TR/TE=107.1/2.3 ms, FA=6°, FOV=16 cm×16 cm, matrix=220×220, ST=3 mm, MT pulse=8 ms Fermi pulse, MT pulse flip angles=0° (MT_{off}) or 1200° (MTₒₙ), offset frequency of MT pulse=1500 Hz, and the number of spokes per MT pulse (m)=9. The MTR map was computed using water images from MT_{off}- and MTₒₙ-siWIFI scans, defined as 1−MTₒₙ/MT_{off}. Additionally, the fat fraction was derived from the MT-siWIFI images by employing water and fat images from the MT_{off}-siWIFI scan. A comparison was made between the fat fraction from the MT_{off}-siWIFI scan and that from the regular siWIFI (no MT preparation) scan to validate the accuracy of fat fraction measurement.

Tolerance of siWIFI to B₀ Inhomogeneity

To assess the field inhomogeneities in the investigated body parts, B₀ maps were acquired using a dual-echo radial imaging sequence (TEs=2.2 ms and 4.4 ms) with a resolution of 4×4×5 mm³ for the hip and liver, and 2×2×5 mm³ for the knee. Additionally, a 50% w/v fat emulsion phantom was prepared to test siWIFI's tolerance to field inhomogeneity. The measured B₀ shift of the phantom was approximately +3.2 Hz. This phantom was then scanned with siWIFI using the following parameters: TR/TE=12.2/2.3 ms, FA=5°, and a resolution of 0.8×0.8×5 mm³. To assess siWIFI's tolerance to B₀ inhomogeneities in fat fraction measurements, the center frequencies of the phantom scans were manually adjusted from −150 Hz to +150 Hz in 50 Hz increments.

### Example Data Analysis

siWIFI image analyses were conducted using custom MATLAB codes (MathWorks, Natick, MA, USA). IDEAL images were processed using the GE-provided analysis pipeline. Regions-of-interest (ROIs) were delineated on the anatomical regions specified in Table 2, and comparisons of fat fractions between siWIFI and IDEAL were performed using Pearson's correlation and Bland-Altman plot analysis. Inter-scan coefficients of variance of fat fraction measurements were computed to assess the repeatability of siWIFI scans. Moreover, the fat fraction measurements obtained from regular siWIFI and MT_{off}-siWIFI were compared using Pearson's correlation. Statistical analyses were conducted using GraphPad Prism 10 (GraphPad Software, Boston, MA, USA).

Table 2 shows repeatability of siWIFI technique. The measured fat fractions were obtained from regions of interest drawn on subregions of the hip, knee, and abdomen. Low interscan coefficient of variance (CoV) values indicate the excellent repeatability of siWIFI. SQ fat=subcutaneous fat.

TABLE 2
Repeatability of siWIFI technique

| | | Scan 1 | Scan 2 | Scan 3 | Interscan |
|---|---|---|---|---|---|
| | | (%) | (%) | (%) | CoV (%) |
| Hip | Femoral Head | 88.9 | 90.7 | 91.9 | 1.6 |
| | Bone Marrow | 81.9 | 85.1 | 84.8 | 2.1 |
| | Vertebra | 40.9 | 41.3 | 40.3 | 1.2 |
| | Muscle | 6.1 | 6.5 | 6.3 | 3.1 |
| Knee | Fat Pad | 83.8 | 82.3 | 81.9 | 1.2 |
| | Femur | 95.1 | 93.4 | 93.3 | 1.1 |
| | Muscle | 7.8 | 7.4 | 7.1 | 4.3 |
| | Cartilage | 9.0 | 8.3 | 9.0 | 4.4 |
| | Tendon | 24.1 | 24.2 | 24.7 | 1.3 |
| Abdomen | Liver | 10.2 | 10.7 | 11.0 | 3.6 |
| | SQ Fat | 97.2 | 97.8 | 97.8 | 0.3 |
| | Muscle | 6.3 | 6.1 | 6.1 | 2.3 |

### Example Results

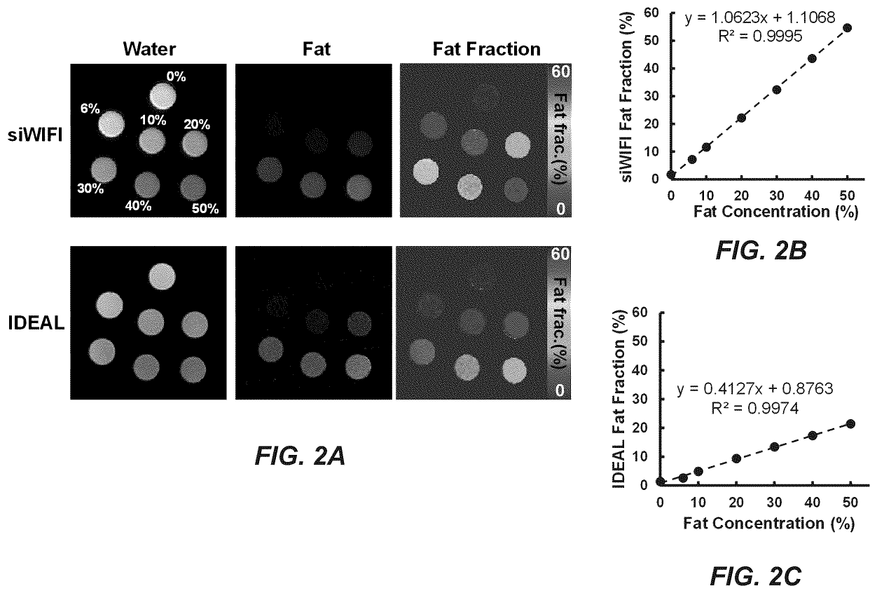

The microlipid phantom scans demonstrate the successful separation of water and fat signals by siWIFI (FIGS. 2A-2C). Fat fractions measured by siWIFI exhibit an outstanding correlation (R²=0.9995, P<0.0001) with the actual lipid concentrations in the phantoms.

FIGS. 2A-2C show example phantom siWIFI imaging results from example implementations of an example embodiment of the disclosed siWIFI technique. FIG. 2A illustrate siWIFI scan results of water and fat phantoms, as well as the fat fraction maps, obtained from the phantoms with varying fat concentrations of 0%, 6%, 10%, 20%, 30%, 40%, and 50% (as indicated on the water image). FIG. 2B compares fat fraction measurements from siWIFI with fat concentrations of these phantoms, showing a high degree of correlation (R²=0.9995, P<0.0001). FIG. 2C compares fat fraction measurements from IDEAL with fat concentrations of these phantoms.

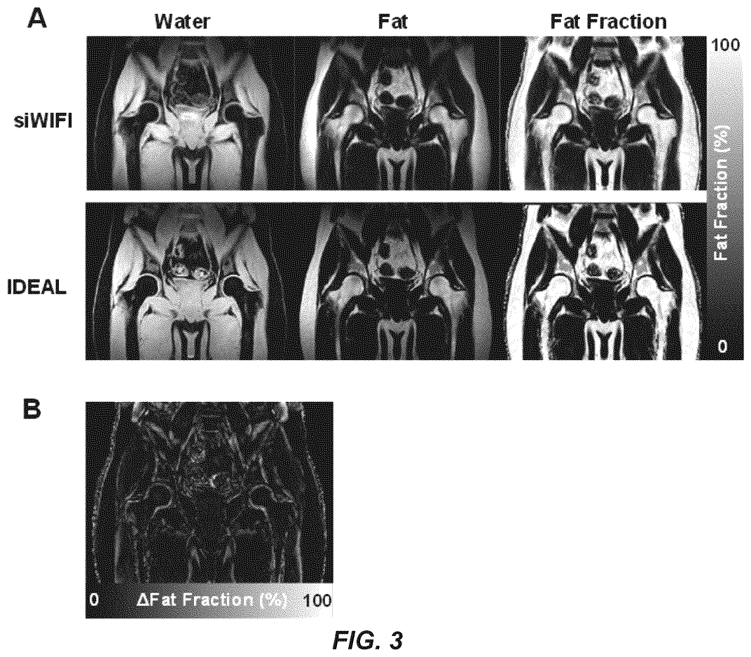

FIG. 3 shows hip siWIFI and IDEAL imaging of a healthy 27-year-old male volunteer. Panel A of FIG. 3 shows water and fat images produced using the siWIFI sequence, as well as fat fraction map (first row), that are comparable to those obtained with IDEAL (second row). The water and fat images, along with the fat fraction map of the hip of the volunteer, generated using siWIFI, are generally similar to those produced by IDEAL. Panel B of FIG. 3 shows the map of fat fraction difference (absolute) between siWIFI and IDEAL.

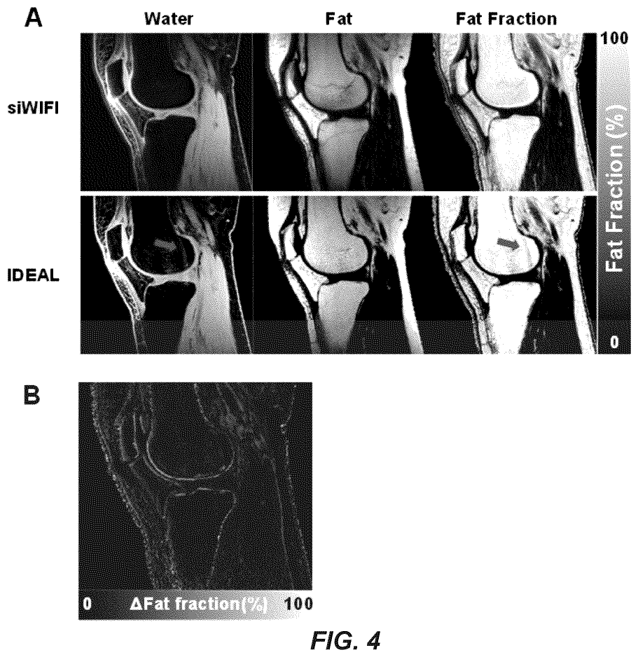

FIG. 4 shows knee siWIFI and IDEAL imaging of a 32-year-old healthy female volunteer. (A) The siWIFI sequence generates similar water and fat images as well as the fat fraction map (first row) to those obtained with IDEAL (second row). Arrows indicate the motion artifacts induced by pulsatile flow in the IDEAL water image and fat fraction map. A similar overall agreement between siWIFI and IDEAL is observed in the knee scans of the volunteer. The IDEAL water image and fat fraction map, however, display an artifact (indicated by arrows), presumably due to pulsatile blood flow. In comparison, these motion-induced artifacts are absent in the siWIFI fat fraction maps. Panel B of FIG. 4 shows the map of fat fraction difference (absolute) between siWIFI and IDEAL.

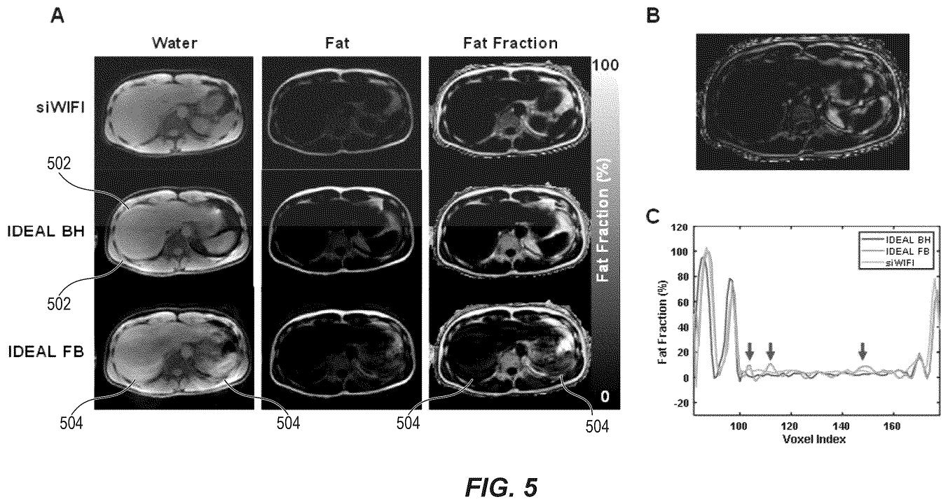

FIG. 5 shows images and a data plot depicting example liver siWIFI and IDEAL imaging data of a 33-year-old healthy male volunteer. Panel A of FIG. 5 shows water and fat images as well as fat fraction maps are obtained from siWIFI and IDEAL respectively. IDEAL images were acquired twice, with (IDEAL BH) and without (IDEAL FB) breath hold. The motion insensitivity of the siWIFI technique is also demonstrated in the liver scans of the volunteer. Although the siWIFI scans were performed with free breathing, no apparent motion artifacts are seen in the water and fat images or the fat fraction map. In comparison, the IDEAL scan with free breathing shows strong motion artifacts 504 in the separated water and fat images as well as the fat fraction map. The IDEAL scan with breath-hold shows much better image quality than the free-breathing scan, although a minor motion artifact 502 at the liver border is still found in the water image (Panel A of FIG. 5). The line profiles of the fat fraction clearly demonstrate the motion artifacts in the free-breathing IDEAL scan as fluctuations (indicated by arrows) that are not seen in the siWIFI or breath-hold IDEAL scans. Panel B of FIG. 5 shows the map of fat fraction difference (absolute) between siWIFI and IDEAL. Panel C of FIG. 5 shows fat fraction profiles along the dashed lines drawn on Panel A of FIG. 5. While fat fraction profiles from siWIFI and IDEAL scans generally match well, arrows indicate artificially increased fat fractions in IDEAL FB due to motion.

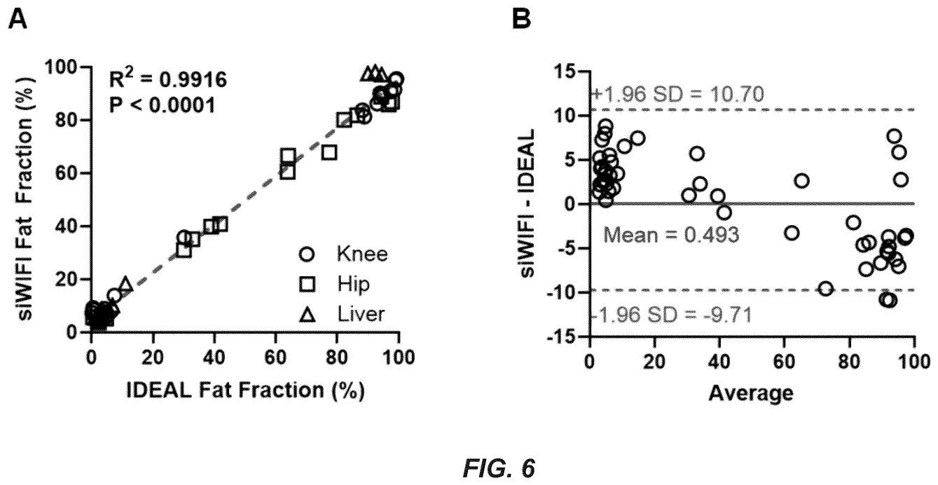

FIG. 6 shows a comparison of fat fractions between siWIFI and IDEAL. (A) Pearson correlation of region-of-interest (ROI)-based fat fraction measurements via siWIFI and IDEAL. The two measurements show significant (P<0.0001) and substantial (R²=0.9916) correlation. Overall, the fat fraction measurements from both methods across all anatomical regions are in excellent agreement. Panel B of FIG. 6 shows a Bland-Altman plot illustrating the agreement of siWIFI and IDEAL fat fraction measurements. The two methods show high agreement between fat fraction measurements.

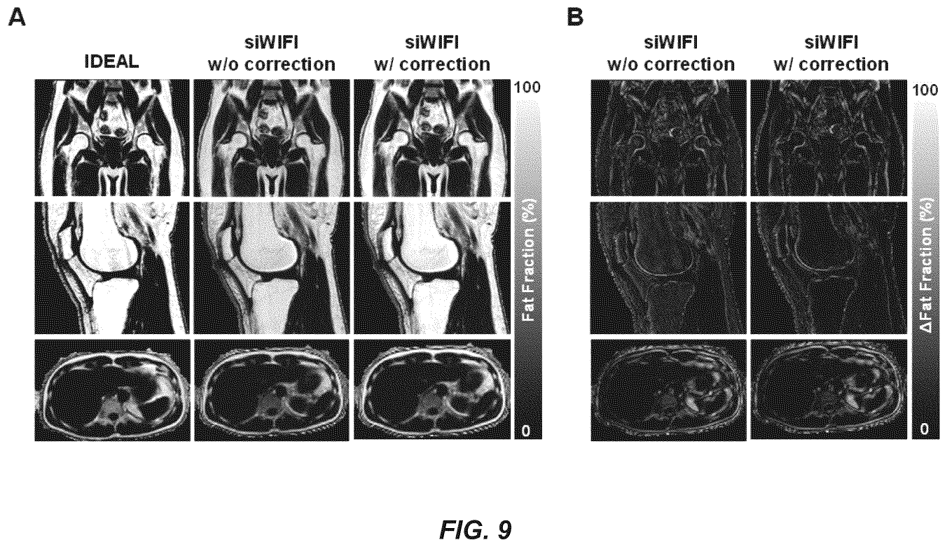

FIG. 9 shows in vivo siWIFI fat fraction maps with and without fat peak correction, and comparisons with IDEAL fat fraction maps. The performance of fat peak correction was evaluated by comparing in vivo siWIFI fat fraction maps, with and without correction, to IDEAL fat fraction maps. After correction, siWIFI fat fractions increased, becoming more consistent with IDEAL results. This improvement is highlighted in the absolute fat fraction difference maps between IDEAL and siWIFI, with the corrected siWIFI maps showing reduced discrepancies. However, in liver scans, the improvement was less pronounced due to differences in breathing phases between IDEAL (end expiration) and siWIFI (averaged phase), which contributed more to the fat fraction variation than the fat peak correction in the difference map.

Panel A of FIG. 9 shows fat fraction maps of the hip, knee, and liver from IDEAL (first column), siWIFI without fat peak correction (second column), and siWIFI with fat peak correction (third column). The fat peak correction leads to increased fat fractions, making them more comparable to IDEAL measurements.

Panel B of FIG. 9 shows absolute fat fraction difference maps between IDEAL and siWIFI. The overall difference between siWIFI and IDEAL fat fractions is reduced after applying the correction.

The repeatability of siWIFI was examined by scanning volunteers three times for each anatomical region (as shown in Table 2). The inter-scan coefficient of variance is around 5% or lower in all anatomical regions, indicating that siWIFI fat fraction measurements are highly repeatable.

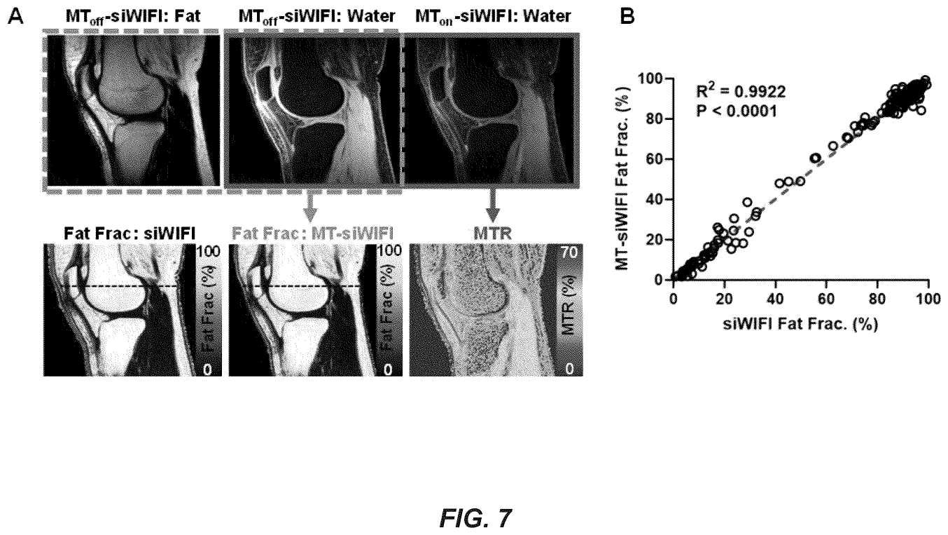

FIG. 7 shows simultaneous magnetization transfer ratio (MTR) and fat fraction mapping via the MT-siWIFI technique. Panel A of FIG. 7 shows representative knee MT-siWIFI images and corresponding fat fraction and MTR maps from a healthy volunteer (32-year-old female). The water and fat images acquired from MT_{off}-siWIFI are used to calculate the fat fraction (Fat Frac: MT-siWIFI, dashed box). The fat fraction map produced from the MT off-si WIFI scan is almost identical to that of the regular siWIFI scan without the MT preparation module. This agreement is further demonstrated by a significant correlation of fat fraction measurements between MT_{off}-siWIFI and regular siWIFI scans (R²=0.9879, P<0.0001; Panel B of FIG. 7). Using the water images from MT_{off}- and MTₒₙ-siWIFI scans, the fat-free MTR map is generated, showing relatively high MTR values in anatomical regions with high organic matrix content, such as tendons, cartilage, and the meniscus. Panel B of FIG. 7 shows the Pearson correlation of MT-siWIFI and siWIFI fat fraction measurements performed using voxels along the dashed lines shown in Panel A, bottom row. The results demonstrate a significant (P<0.0001) and substantial (R²=0.9922) correlation between these fat fraction measurements.

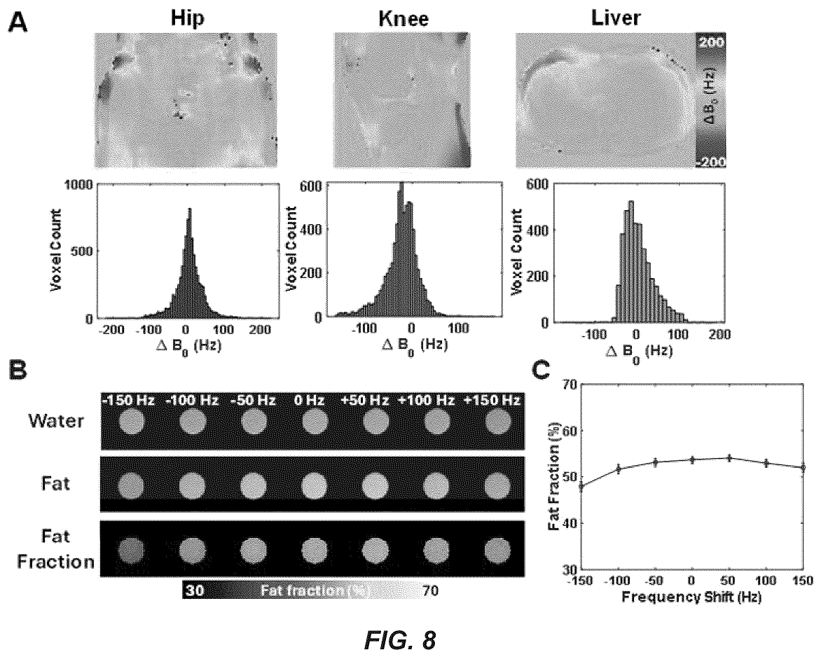

FIG. 8 shows an investigation of B₀ inhomogeneity tolerance of siWIFI fat fraction measurement. Panel A of FIG. 8 shows B₀ maps of the hip, knee, and liver estimated using dual-echo imaging, along with histograms of B₀ shift measurements. Most B₀ shifts fall within the range of −100 to +100 Hz. Panel B of FIG. 8 shows siWIFI fat fraction maps of a 50% w/v fat emulsion phantom with manual center frequency adjustments ranging from −150 to +150 Hz in 50 Hz increments. Panel C of FIG. 8 shows siWIFI-measured fat fractions at each center frequency adjustment shown in Panel B. At each center frequency adjustment, the fat fractions remain mostly consistent, with only a 2.4% variation (ranging from 51.7% to 54.1%) within the −100 to +100 Hz range.

As shown in the estimated B₀ inhomogeneity maps of Panel A of FIG. 8, the B₀ shifts predominantly ranged from −100 to +100 Hz. Therefore, the center frequency adjustment of siWIFI phantom imaging from −150 to +150 Hz adequately covered the practical range of conditions. Panels B and C of FIG. 8 demonstrate that the siWIFI-measured fat fractions remained relatively stable across the tested center frequencies, with only a 2.4% variation (ranging from 51.7% to 54.1%) within the −100 to +100 Hz range. A slight underestimation of the fat fraction was observed at a −150 Hz shift, approximately half the bandwidth of the excitation pulse.

### Discussion of Example Results

In these example implementations, we developed a novel spectrally selective, interleaved water and fat imaging sequence for quantifying fat fraction. The fat fraction quantification of siWIFI was validated using microlipid phantom scans, which showed an excellent correlation between the measured fat fraction and the actual fat concentrations in the series of phantoms. In vivo scans of healthy volunteers at various anatomical regions showed robust separation of water and fat images, with fat fraction measurements aligning with those from IDEAL scans. Notably, the motion artifacts from blood flow and respiration observed in IDEAL scans were much reduced in siWIFI images. Incorporating the MT preparation module enabled the simultaneous quantification of fat fraction and MTR, which can be a useful approach for targeting fat infiltration and fibrosis.

The selective excitation of water and fat in siWIFI fundamentally avoids the water-fat swap issue observed in IDEAL and enables accurate fat quantification. The phantom study showed an excellent linear correlation (e.g., R²=0.9995) between the actual lipid concentration in the phantom and the fat quantification measurement from siWIFI, indicating the high accuracy of si WIFI for fat quantification.

The radial acquisition scheme employed in siWIFI has the advantage of mitigating motion artifacts, as seen in the knee and liver images. The pulsatile flow artifact from the popliteal artery is a common issue in knee MR images. Previously, propeller acquisition schemes have been demonstrated to suppress such pulsatile flow artifacts in knee images. Since the propeller acquisition schemes are variants of radial acquisitions, the same underlying principle appears to mitigate the pulsatile artifact in siWIFI scans, unlike the IDEAL images that show motion artifacts. This motion insensitivity was also observed in the liver siWIFI with free breath. This free-breathing abdominal MRI technique is particularly important for patient populations unable to undergo breath-hold scans, such as pediatric patients. Consistent with previous studies utilizing radial or similar center-out acquisition schemes for liver R₂*, quantitative susceptibility mapping, and fat fraction measurement, the free-breathing siWIFI scans exhibited comparable image quality to IDEAL scans with breath-hold. For more time-efficient k-space sampling with the center-out scheme, the radial acquisition in siWIFI can be replaced by other sampling methods commonly used in ultrashort echo time (UTE) imaging, such as cones and stack-of-stars approaches. Cartesian sampling is also compatible when a short TE is not necessary.

There are two methods for implementing interleaved acquisition: interleaved spokes or interleaved segments. In this study, the interleaved segments strategy was utilized for data acquisition to generate fat and water images due to its ease of implementation within our sequence structure. Panel (B) of FIG. 7 demonstrates a strong linear correlation of fat fractions between MT-siWIFI and siWIFI, highlighting the effectiveness of the interleaved segments strategy. Further studies are warranted to compare the performance of fat fraction quantification between these two interleaved acquisition strategies.

The siWIFI method is similar to the commonly used spectrally selective fat saturation technique in that both leverage the chemical shift of fat for spectral selection using a narrow bandwidth RF pulse. Typically, fat saturation is performed using a maximum-phase pulse to maximize the signal decay during RF excitation, followed by a spoiler gradient. In contrast, the disclosed siWIFI sequence employs a minimum-phase design to achieve minimized TE for the effective excitation of water and fat signals, rather than saturating them. Furthermore, the siWIFI technique not only generates water-selective images but also quantifies fat fractions, whereas fat saturation is typically utilized solely for water imaging.

The phantom study confirmed that siWIFI fat fraction measurements remain accurate within a B₀ inhomogeneity range of −100 to +100 Hz for the in vivo cases. Deviations in fat fraction measurements began at −150 Hz, as expected, since this closely corresponds to half of the siWIFI RF excitation pulse bandwidth (166 Hz). Numerical simulations were also conducted to investigate the tolerance of siWIFI fat fraction measurements to B₁ inhomogeneity. Considering B₁ inhomogeneity, the spoiled gradient echo (SPGR)-like signal equation for both water and fat imaging in siWIFI was used to calculate the fat fraction. Assuming TR/TE=11/2.3 ms, θ=5°, T_{1w}/T₂*_{w} (muscle)=1400/30 ms, T_{1f}/T₂*f=400/25 ms, and a 50% fat fraction, the estimated fat fractions vary by +1.3% with rB₁ ranging from 0.8 to 1.2. This indicates that siWIFI fat fraction measurements are almost insensitive to B₁ inhomogeneity. This insensitivity is primarily due to the use of a relatively low flip angle in siWIFI, which is designed for proton density-weighted contrast imaging.

In this study, the fat peak correction procedure effectively reduced the overall underestimation of siWIFI fat fraction measurements, making them more comparable to IDEAL measurements. Additionally, variations in T₂* values among different tissues may lead to biases in fat fraction quantification in siWIFI, particularly when TE is not sufficiently short relative to tissue T₂*. Therefore, applying R₂* correction with known tissue T₂* values may further improve the accuracy of fat fraction calculation in siWIFI. A future study is warranted to assess the effect of R₂* correction on fat fraction measurement.

The minimum-phase method was used to design the spectrally selective RF pulse with the goal of achieving a minimized TE in this study. Prolonging the duration of this RF pulse is essential to preserve spectrum selectivity, particularly at lower field strengths where the chemical shift between water and fat is reduced. Consequently, this RF pulse elongation results in an extended minimum TE at low field strengths. Greater emphasis on R₂* correction is typically necessary for more precise quantification of fat fraction as TE is prolonged. However, at lower field strengths, T₂* is increased due to the reduced tissue susceptibility, indicating that R₂* correction becomes less critical. Therefore, the effectiveness of R₂* correction in improving fat fraction quantification depends on both the minimum TE and T₂*.

The feasibility of simultaneous fat fraction measurement and fat-suppressed quantitative MRI was demonstrated by incorporating an MT preparation pulse into the siWIFI sequence. The MT-added siWIFI sequence not only generated MTR maps but also produced fat fraction maps identical to those from the regular siWIFI sequence without the MT pulse. The simultaneous measurement of fat-suppressed MTR (sensitive to macromolecular changes) and fat fraction via MT-siWIFI is expected to be valuable for accurately monitoring metabolic and inflammatory diseases, where fat infiltration and fibrosis are common sequelae. Yet, the motion robustness of siWIFI mentioned above only applies to water and fat images acquired within the same scan. If motion occurs between MT on and MT off scans, motion registration using Elastix software will be required to align the tissues for accurate MTR quantification.

In our in vivo studies, siWIFI images appeared blurrier than IDEAL images. This blurriness likely results from imperfect center-out radial imaging induced by off-resonance effects and insufficient correction for eddy currents. It is notably evident in the difference map between IDEAL and siWIFI fat fractions, where the fat fraction difference is more pronounced at tissue boundaries compared to within tissues, reflecting differences in image sharpness between siWIFI and IDEAL. Our MRI system is equipped only with a linear shimming system. We anticipate that employing a high-order shimming system would reduce off-resonance-induced blurriness in siWIFI. Additionally, we only measured and corrected gradient delays to mitigate eddy current effects. An accurate k-space trajectory measurement would be more effective in correcting eddy current-induced artifacts in non-Cartesian imaging.

The disclosed siWIFI sequence provides inherently co-registered fat and water images along with fat quantification. Moreover, the sequence can be seamlessly integrated with magnetization preparation modules, enabling concurrent fat fraction measurement alongside other quantitative MR parameters.

As disclosed above, the example embodiments and implementations of the siWIFI techniques can use a narrow bandwidth RF pulse for selective excitation of water and fat separately. The interleaved acquisition method ensures that the obtained water and fat images are inherently co-registered. A radial sampling strategy further reduces motion-induced artifacts. Phantoms with lipid concentrations ranging from 0% to 50% were scanned to measure fat fraction. Moreover, healthy volunteers were scanned to assess the in vivo feasibility of fat fraction measurement at the hip, knee, and liver. In vivo fat fraction measurements were compared with those from vendor-provided IDEAL scans. Furthermore, a magnetization transfer (MT) preparation module was incorporated to demonstrate the feasibility of simultaneous measurement of fat fraction and MT ratio (MTR) utilizing the siWIFI framework.

Example results from example implementations include the following. The phantom fat fractions measured by siWIFI showed excellent correlation with lipid concentrations (R²=0.9995, P<0.0001). In vivo studies demonstrated that the fat fractions obtained from siWIFI were comparable to those from IDEAL. Additionally, siWIFI demonstrates reduced motion artifacts from pulsatile flow in knee imaging compared to IDEAL scans and exhibits less sensitivity to respiratory motion in liver imaging compared to IDEAL scans without breath-hold. The knee imaging study demonstrated that MT-prepared siWIFI is capable of generating fat fraction and MTR maps simultaneously. Therefore, the disclosed siWIFI sequence allows selective water-fat imaging and quantification with reduced motion artifacts.

Example siWIFI MRI Method

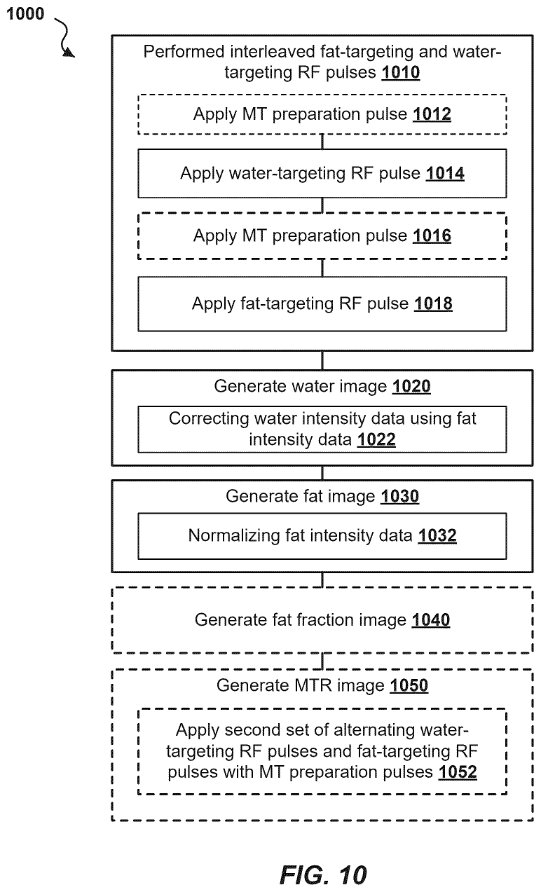

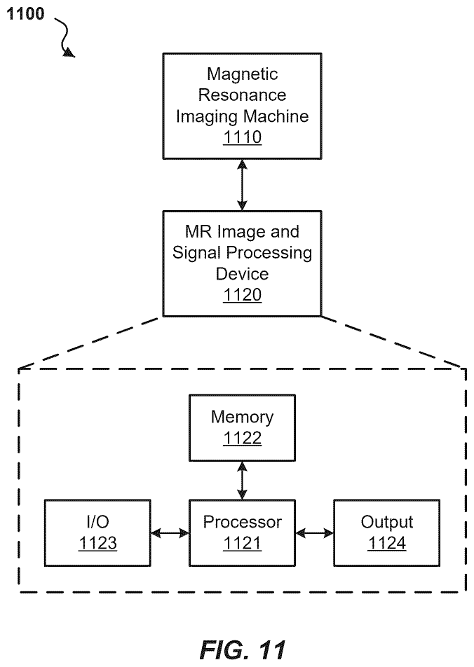

FIG. 10 is a flow diagram illustrating an example method 1000 for characterizing tissue by selectively imaging water and fat. In some embodiments, the method 1000 is performed by components of one or more computing systems and/or MRI systems, such as the example system 1100 including the MRI machine 1110 and the MR image and signal processing device 1120, shown later in FIG. 11.

The method 1000 can include, at operation 1010, performing interleaved fat-targeting and water-targeting radio frequency (RF) pulses. In some implementations, operation 1010 includes alternatively applying RF pulses of a first type (e.g., that selectively excite water) and RF pulses of a second type (e.g., that selectively excite fat) to generate first MR data and second MR data, respectively. The RF pulses of the second type can excite fat peaks, such as fat peaks corresponding to one or more of 0.9 ppm, 1.2 ppm, 1.6 ppm, 2.0 ppm, or 2.3 ppm. The RF pulses of the first type can also excite certain fat peaks, such as fat peaks corresponding to one or more of 4.1 ppm, 4.3 ppm, 5.2 ppm, and 5.3 ppm. The first and second MR data can be k-space data, corresponding to intensities that encode data about the spatial variation of nuclei. In some embodiments, the system can apply a particular number of RF pulses of the first type, followed by the particular number of RF pulses of the second type. For example, the system can apply 9 RF pulses of the first type followed by 9 RF pulses of the second type.

In some embodiments, the RF pulses (e.g., of both the first and second types) are narrow-bandwidth soft pulses. For example, the RF pulses can have a bandwidth of less than 400 Hz, such as between 300 Hz and 350 Hz (e.g., substantially equal to 333 Hz). Additionally, or alternatively, the RF pulses can have a duration of greater than 6 ms, such as between 6 ms and 7 ms (e.g., substantially equal to 6.6 ms). In some embodiments, the RF pulses are configured with a minimum-phase design having a short peak-to-end duration. For example, the RF pulses can have a peak-to-end duration of less than 3 ms, such as between 2 ms and 2.5 ms (e.g., substantially equal to 2.3 ms). In some embodiments, the system uses an echo time (TE) (e.g., a time between a peak of an RF pulse and a time of measuring a resulting RF signal) of less than 3 ms, such as between 2 ms and 2.5 ms (e.g., substantially equal to 2.3 ms). In some embodiments, the RF pulses have a repetition time (TR) of between 8 ms and 15 ms (e.g., substantially equal to 9.7 ms, 11.8 ms, or 12 ms).

In some embodiments, the first and second MR data are acquired according to a center-out radial sampling method. For example, each RF pulse can correspond to a radial spoke in k-space (e.g., correspond to one or more intensities in k-space that are aligned radially outwards from the center of k-space). For example, an RF pulse can be used to generate all measured intensities along a single radial spoke.

In some embodiments, the system applies an MT preparation pulse before each of the particular number of RF pulses of the first type and/or the particular number of RF pulses of the second type. For example, the system can perform an MT preparation pulse between RF pulses of the first type and RF pulses of the second type.

As an illustrative example of performing interleaved fat-targeting and water-targeting RF pulses, the method 1000 can include, at operation 1012, applying an MT preparation pulse. For example, the system can apply an 8 ms Fermi pulse corresponding to an MT flip angle of 0° or 1200°. The method 1000 can include, at operation 1014, applying an RF pulse of the first type (e.g., a water-targeting RF pulse). In some implementations, the method 1000 includes applying multiple RF pulses of the first type. The method 1000 can include, at operation 1016, applying an MT preparation pulse (e.g., with the same parameters as the MT pulse applied at 1012). The method 1000 can include, at operation 1018, applying an RF pulse of the second type (e.g., a fat-targeting RF pulse). In some implementations, the method includes applying multiple RF pulses of the second type. The method 1000 can include performing the RF pulse operations 1012-1018 multiple times (e.g., once for each k-space spoke) to generate the first MR data and the second MR data.

The method 1000 can include, at operation 1020, generating a water image depicting spatially-dependent water intensity data. Generating the water image can include processing the first MR data, such as by taking an inverse Fourier transform of the first MR data.

As an illustrative example of generating the water image, the method 1000 can include, at operation 1022, generating a corrected water intensity data by correcting water intensity data using fat intensity data. For example, the method 1000 can include subtracting scaled fat intensity data, derived from the second MR data, from the first MR data. The subtracted scaled fat intensity data can be scaled based on a proportion of fat intensity expected to be present in the water intensity data (e.g., an amount of fat excited by the RF pulses of the first type). In some embodiments, scaled subtracted fat intensity is scaled to between 10% and 15% compared to the fat intensity data derived from the second MR data (e.g., substantially equal to 12% of the fat intensity data derived from the second MR data).

The method 1000 can include, at operation 1030, generating a fat image depicting spatially-dependent fat intensity data. Generating the fat image can include processing the second MR data, such as by taking an inverse Fourier transform of the second MR data.

As an illustrative example of generating the fat image, the method 1000 can include, at operation 1032, generating a corrected fat intensity data by normalizing fat intensity data by scaling the fat intensity data by a scale factor. The scale factor can be based on a proportion of fat expected to be present in the fat intensity data (e.g., an amount of fat excited by the RF pulses of the second type). In some embodiments, the fat intensity data is between 85% and 90% of the intensity of the scaled fat intensity data (e.g., substantially equal to 87.8% of the intensity of the scaled fat intensity data).

The method 1000 can include, at operation 1040, generating a fat fraction image. The fat fraction image can depict spatially-dependent ratio intensity data, where the ratio intensity data corresponds to a ratio between fat and water intensities. The ratio intensity data can be determined using the first MR data and the second MR data, such as by using water intensity data and fat intensity data (e.g., the corrected water intensity data and the corrected fat intensity data). In some implementations, each intensity value of the ratio intensity data can correspond to a fat intensity value divided by the sum of the fat intensity value and a corresponding water intensity value. For example, a ratio intensity value corresponding to a particular point (e.g., a spatial point in a resulting ratio image, a k-space point of k-space MR data) can equal a fat intensity value corresponding to the particular point (e.g., from the corrected fat intensity data) divided by the sum of the fat intensity value and a water intensity value corresponding to the particular point (e.g., from the corrected water intensity data).

The method 1000 can include, at operation 1050, generating an MT ratio (MTR) image. For example, if the method 1000 includes applying MT preparation pulses at operations 1012 and/or 1016, then the method 1000 can include applying MT preparation pulses with a different set of parameters to generate additional water intensity data and/or fat intensity data, and an MTR image can be generated from the sets of water intensity data and/or sets of fat intensity data.

As an illustrative example of generating an MTR image, the method 1000 can include, at 1052, applying a second set of MT preparation pulses with alternating water-targeting RF pulses and fat-targeting RF pulses. In some implementations, the method 1000 includes applying, at operation 1010, a first set of alternating pulses by alternatively applying (a) an MT preparation pulse of a first type and a particular number of RF pulses of the first type (e.g., water-targeting RF pulses) and (b) an MT preparation pulse of the first type and a particular number of RF pulses of the second type (e.g., fat-targeting RF pulses). The system can generate, by applying the first set of alternating pulses, first MR data (e.g., corresponding to the RF pulses of the first type) and second MR data (e.g., corresponding to the RF pulses of the second type). The MT preparation pulse of the first type can correspond to an MT flip angle near 0° (e.g., less than) 5°. The method 1000 can include applying, at 1052, a second set of alternating pulses by alternatively applying (a) an MT pulse of a second type followed by RF pulses of the first type (e.g., water-targeting RF pulses) and (b) an MT pulse of the second type followed by RF pulses of the second type (e.g., fat-targeting RF pulses). The MT preparation pulse of the second type can correspond to a large MT flip angle (e.g., between 1000° and 1500°, such as substantially equal to) 1200°. The system can generate, by applying the second set of alternating pulses, third MR data (e.g., corresponding to the RF pulses of the first type) and fourth MR data (e.g., corresponding to the RF pulses of the second type). The method 1000 can include generating a corrected third MR data. For example, the fourth MR data can be used to remove a presence of fat in the third MR data, such as by subtracting scaled fat intensity data, derived from the fourth MR data, from the third MR data. The method 1000 can include processing third MR data (e.g., corrected third MR data) to generate a third MR image (e.g., depicting spatially-dependent water intensity data) and can include processing fourth MR data to generate a fourth MR image (e.g., depicting spatially-dependent fat intensity data). The method 1000 can include generating the MTR image by processing a corrected first MR data and the corrected third MR data. For example, an MTR data value corresponding to a particular point (e.g., a spatial point in a resulting ratio image, a k-space point of k-space MR data) can correspond a ratio between an intensity value of the corrected first MR data corresponding to the particular point and an intensity value of the corrected third MR data corresponding to the particular point (e.g., the intensity value of the corrected third MR data divided by the intensity value of the corrected first MR data, subtracted from 1).

### Example MRI System

FIG. 11 shows a diagram of an example embodiment of a system 1100 that includes a magnetic resonance imaging (MRI) machine 1110 in communication with an MR image and signal processing device 1120, e.g., which can be used to control the MRI machine and analyze obtained data to affect the image data collecting protocol to produce quantitative data in accordance with the siWIFI pulse sequence and overall siWIFI technique.

The MRI machine 1110 can be used in the system 1100 to implement a MRI-based characterization process in accordance with example embodiments of the siWIFI method of the present technology under the control of the example MR image and signal processing device 1120. MRI machine 1110 can include various types of MRI systems, which can perform at least one of a multitude of MRI scans that can include, but are not limited to, T1-weighted MRI scans, T1ρ MRI scans, T2-weighted MRI scans, T2*-weighted MRI scans, spin (proton (1H)) density weighted MRI scans, diffusion tensor (DT) and diffusion weighted imaging (DWI) MRI scans, magnetization transfer (MT) MRI scans, real-time MRI, functional MRI (fMRI) and related techniques such as arterial spin labeling (ASL), among other MRI techniques.

The MR image and signal processing device 1120 can include a processor 1121 that can be in communication with a memory unit 1122, an input/output (I/O) unit 1123, and/or an output unit 1124. The MR image and signal processing device 1120 can be implemented as one of various data processing systems, such as a personal computer (PC), laptop, and mobile computing device such as a smartphone, tablet and/or wearable computing device. In some implementations, the MR image and signal processing device 1120 is embodied on one or more computing devices in a computer system or communication network accessible via the Internet (referred to as “the cloud”), e.g., including servers and/or databases in the cloud.

The processor 1121 is configured to process data, and the memory unit 1122 is in communication with the processor 1121 to store and/or buffer the data. To support various functions of the MR image and signal processing device 1120, the processor 1121 can be included to interface with and control operations of other components of the MR image and signal processing device 1120, such as the I/O unit 1123 and/or the output unit 1124. The processor 1121 can include one or more processors, e.g., including but not limited to microprocessors such as a central processing unit (CPU), microcontrollers, or the like.

The memory unit 1122 can include and store processor-executable code, which when executed by the processor, configures the MR image and signal processing device 1120 to perform various operations, e.g., such as receiving information, commands, and/or data, processing information and data, and transmitting or providing information/data to another device. The memory unit 1122 can store other information and data, such as instructions, software, values, images, and other data processed or referenced by processor 1121. For example, various types of Random Access Memory (RAM) devices, Read Only Memory (ROM) devices, Flash Memory devices, and other suitable storage media can be used to implement storage functions of memory unit 1122. The memory unit 1122 can store MRI data and information, which can include subject MRI image data including spatial and spectral data, MRI machine system parameters, data processing parameters, and processed parameters and data that can be used in the implementation of MR signal and data processing techniques, including siWIFI MRI techniques in accordance with the disclosed technology. The memory unit 1122 can store data and information that can be used to implement a MRI-based imaging and signal characterization method, e.g., including one or more algorithms for implementing a siWIFI method, and store data and information that can be generated from a MRI-based siWIFI algorithm and model.

In some implementations, the MR image and signal processing device 1120 includes an input/output unit (I/O) 1123 to interface the processor 1121 and/or memory unit 1122 to other modules, units or devices associated with the system 1100, and/or external devices. The I/O unit 1123 can connect to an external interface, source of data storage, or display device. Various types of wired or wireless interfaces compatible with typical data communication standards, such as Universal Serial Bus (USB), IEEE 1394 (FireWire), Bluetooth, Bluetooth low energy (BLE), ZigBee, IEEE 802.11, Wireless Local Area Network (WLAN), Wireless Personal Area Network (WPAN), Wireless Wide Area Network (WWAN), WiMAX, IEEE 802.16 (Worldwide Interoperability for Microwave Access (WiMAX)), 3G/4G/LTE/5G/6G cellular communication methods, and parallel interfaces, can be used to implement I/O unit 1123. In some implementations, for example, the MR image and signal processing device 1120 includes a wireless communications unit, e.g., such as a transmitter (Tx) or a transmitter/receiver (Tx/Rx) unit. The I/O unit 1123 can interface the processor 1121 and memory unit 1122 with the wireless communications unit to utilize various types of wireless interfaces, such as the examples described above. The I/O unit 1123 can interface with other external interfaces, sources of data storage, and/or visual or audio display devices, etc. to retrieve and transfer data and information that can be processed by the processor 1121, stored in the memory unit 1122, or exhibited on an output unit of a user device (e.g., display screen of a computing device) or an external device.

To support various functions of the MR image and signal processing device 1120, the output unit 1124 can be used to exhibit data implemented by the example device 1120. The output unit 1124 can include various types of display, speaker, or printing interfaces to implement output functionalities of the system 1100. In some embodiments, for example, the output unit 1124 can include cathode ray tube (CRT), light emitting diode (LED), or liquid crystal display (LCD) monitor or screen as a visual display. In some examples, the output unit 1124 can include toner, liquid inkjet, solid ink, dye sublimation, inkless (such as thermal or UV) printing apparatuses to implement some output modalities of the output unit 1124. In some examples, the output unit 1124 can include various types of audio signal transducer apparatuses. The output unit 1124 can exhibit data and information, such as patient diagnostic data, MRI machine system information, partially processed MRI-based siWIFI processing information, and/or fully-processed MRI-based si WIFI processing information.

The disclosed siWIFI techniques and systems can be used for a variety of applications. In some implementations, for example, the disclosed siWIFI techniques can be utilized for quantifying fat fractions in all the different body regions. Incorporating the MT preparation module enabled the simultaneous quantification of fat fraction and MTR, which can be a useful approach for targeting fat infiltration and fibrosis.

### EXAMPLES

In some embodiments in accordance with the disclosed technology (example A1), a magnetic resonance imaging (MRI) method for characterizing tissue includes acquiring magnetic resonance (MR) data from a tissue using an MRI system in accordance with a spectrally-selective and interleaved water imaging and fat imaging (siWIFI) procedure that uses a narrow bandwidth radio frequency (RF) pulse sequence for selective excitation of water and fat separately in a tissue; and processing the acquired MR data to produce images from the acquired MR data that depicts the water content and the fat content in the tissue.

Example A2 includes the method of example A1 or any of examples A1-A14, wherein the produced images include water images and fat images that are inherently co-registered.

Example A3 includes the method of example A1 or any of examples A1-A14, wherein the narrow bandwidth RF pulse sequence includes a pulse with a spectral bandwidth of substantially 333 Hz.

Example A4 includes the method of example A1 or any of examples A1-A14, wherein the narrow bandwidth RF pulse sequence includes a duration of substantially 6.6 ms.

Example A5 includes the method of example A1 or any of examples A1-A14, wherein the narrow bandwidth RF pulse sequence includes a peak-to-end duration of 2.3 ms.

Example A6 includes the method of example A1 or any of examples A1-A14, wherein the acquiring the MR data includes exciting fat peaks from the tissue using a fat-selective imaging protocol, and wherein the acquired MR data includes a plurality of fat peaks corresponding to one or more of 0.9 ppm, 1.2 ppm, 1.6 ppm, 2.0 ppm, and/or 2.3 ppm.

Example A7 includes the method of example A6 or any of examples A1-A14, wherein the processing the acquired MR data includes adjusting water peaks based on fat signal intensity to obtain discernable additional fat peaks corresponding to at least one of 4.1 ppm, 4.3 ppm, 5.2 ppm, and 5.3 ppm in the acquired MR data.

Example A8 includes the method of example A7 or any of examples A1-A14, wherein adjustment of the water peaks is based on a fat signal intensity ratio corresponding to a range of 87% to 88.5% of a total area of a full fat spectrum.

Example A9 includes the method of example A7 or example A8 or any of examples A1-A14, wherein the processing the acquired MR data further includes adjusting water images by subtracting a portion of the fat signal intensity.

Example A10 includes the method of example A9 or any of examples A1-A14, wherein the portion of the fat signal intensity includes a value in a range of 11.5% to 13%.

Example A11 includes the method of example A1 or any of examples A1-A14, wherein the acquiring the MR data includes toggling a center frequency of an excitation pulse of the narrow bandwidth RF pulse sequence between a water frequency and a fat frequency for every k-space spoke that is acquired.

Example A12 includes the method of example A1 or any of examples A1-A14, wherein the acquiring the MR data includes radially sampling the tissue to mitigate motion-induced artifacts from being included in the acquired MR data.

Example A13 includes the method of example A1 or any of examples A1-A14, wherein the narrow bandwidth RF pulse sequence includes a minimum-phase design that is operable to minimize echo time (TE) for an excitation of water and fat signals.

Example A14 includes the method of example A1 or any of examples A1-A13, wherein the processing the MR data further comprises quantifying fat fractions.

In some embodiments in accordance with the disclosed technology (example A15), a system for performing the MRI method of any of examples A1-A14, where the system includes an MRI acquisition machine; and a data processing device comprising a processor and a memory, wherein the memory is configured to store instructions of a computer program product, which when executed by the processor, causes the system to perform the MRI method of any of examples A1-A14.

### CONCLUSION

Implementations of the subject matter and the functional operations described in this patent document can be implemented in various systems, digital electronic circuitry, or in computer software, firmware, or hardware, including the structures disclosed in this specification and their structural equivalents, or in combinations of one or more of them. Implementations of the subject matter described in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of nonvolatile memory, media and memory devices, including by way of example semiconductor memory devices, e.g., EPROM, EEPROM, and flash memory devices. The processor and the memory can be supplemented by, or incorporated in, special purpose logic circuitry.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A magnetic resonance imaging (MRI) method for characterizing tissue, the method comprising:
alternatively applying radio frequency (RF) pulses of a first type and a second type to generate first magnetic resonance (MR) data and second MR data, respectively,
wherein the RF pulses of the first type selectively excite water,
wherein the RF pulses of the second type selectively excite fat;
processing the first MR data to produce a first MR image,
wherein the first MR image depicts water intensity data; and
processing the second MR data to produce a second MR image,
wherein the second MR image depicts fat intensity data.

2. The MRI method of claim 1, wherein the RF pulses of the first type and the RF pulses of the second type have a bandwidth of less than 400 Hz or a duration of greater than 6 ms.

3. The MRI method of claim 1, wherein the RF pulses of the first type and the RF pulses of the second type have a peak-to-end duration of less than 3 ms.

4. The MRI method of claim 1, wherein a repetition time (TR) is between 8 ms and 15 ms.

5. The MRI method of claim 1, wherein an echo time (TE) is between 2 ms and 2.5 ms.

6. The MRI method of claim 1, wherein each RF pulse of the first type corresponds to a radial spoke of k-space data in the first MR data, and wherein each RF pulse of the second type corresponds to a radial spoke of k-space data in the second MR data.

7. The MRI method of claim 1, wherein the RF pulses of the second type excite fat peaks corresponding to one or more of 0.9 ppm, 1.2 ppm, 1.6 ppm, 2.0 ppm, or 2.3 ppm.

8. The MRI method of claim 1, wherein processing the first MR data to produce the first MR image comprises:
generating a corrected first MR data that includes a reduced a presence of fat by subtracting, from the first MR data, scaled fat intensity data derived from the second MR data.

9. The MRI method of claim 8, wherein the scaled fat intensity data is scaled by 10% to 15%.

10. The MRI method of claim 9, comprising:
scaling the second MR data by a scale factor to generate corrected second MR data,
wherein the second MR data is between 85% and 90% of the intensity of the corrected second MR data; and
processing the corrected first MR data and the corrected second MR data to generate a fat fraction image,
wherein an intensity of the fat fraction image corresponds to a ratio between fat and water.

11. The MRI method of claim 1, wherein alternatively applying RF pulses of the first type and the second type comprises:
applying a particular number of RF pulses of the first type, and
subsequently applying the particular number of RF pulses of the second type.

12. The MRI method of claim 1, comprising:
applying, between RF pulses of the first type and RF pulses of the second type, a magnetization transfer (MT) preparation pulse.

13. The MRI method of claim 12, wherein at least one flip angle of the MT preparation pulse is substantially 0° or 1200°.

14. The MRI method of claim 12, comprising:
alternatively applying (a) an MT preparation pulse of a second type followed by RF pulses of the first type (b) an MT preparation pulse of the second type followed by RF pulses of the second type to generate third MR data and fourth MR data, respectively;
generating a corrected first MR data by using the second MR data to remove a presence of fat in the first MR data,
generating a corrected third MR data by using the fourth MR data to remove a presence of fat in the third MR data; and
generating an MT ratio (MTR) image by processing the corrected first MR data and the corrected third MR data.

15. At least one non-transitory, computer-readable storage medium comprising instructions recorded thereon, wherein the instructions when executed by at least one data processor of a magnetic resonance imaging (MRI) device, cause the MRI device to:
alternatively apply radio frequency (RF) pulses of a first type and a second type to generate first magnetic resonance (MR) data and second MR data, respectively,
process the first MR data to produce a first MR image; and
process the second MR data to produce a second MR image.

16. The at least one non-transitory, computer-readable storage medium of claim 15, wherein the RF pulses of the first type are configured to selectively excite fat, and wherein the RF pulses of the second type are configured to selectively excite water.

17. The at least one non-transitory, computer-readable storage medium of claim 16, wherein an echo time (TE) corresponds to an in-phase condition time of water and fat.

18. The at least one non-transitory, computer-readable storage medium of claim 16, wherein processing the first MR data to produce the first MR image comprises:
scaling an intensity of the second MR data by a scaling factor to generate corrected second MR data,
wherein the scaling factor reflects a fraction of total fat excited by RF pulses of the first type;
subtracting, from the first MR data, fat intensity data derived from the second MR data to generate corrected first MR data,
where the fat intensity data reflects a fraction of the total fat excited by RF pulses of the first type; and
processing the corrected first MR data and the corrected second MR data to generate a fat fraction image,
wherein an intensity of the fat fraction image corresponds to a ratio between fat and water.

19. The at least one non-transitory, computer-readable storage medium of claim 15, wherein each RF pulse of the first type corresponds to a radial spoke of k-space data in the first MR data, and wherein each RF pulse of the second type corresponds to a radial spoke of k-space data in the second MR data.

20. The at least one non-transitory, computer-readable storage medium of claim 15, wherein the RF pulses of the first type and the RF pulses of the second type are narrow-bandwidth soft RF pulses with a bandwidth of less than 400 Hz or a duration of greater than 6 ms.
